(19) United States
(12) Patent Application Publication
(10) Pub. No.: US 2008/0169551 A1
(43) Pub. Date: Jul. 17, 2008

(54) IC chip package with near substrate scale chip attachment

(75) Inventors: Wen-Jeng Fan, Hukou Shiang (TW); Li-Chih Fang, Hukou Shiang (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/653,422

(22) Filed: Jan. 16, 2007

(51) Int. Cl. H01L 23/13

(52) U.S. Cl. 257/690; 257/E23.004; 257/E23.021; 257/E23.124

(57) ABSTRACT

An IC package with a near-substrate-scale die-attaching layer includes a substrate, a near-substrate-scale die-attaching layer, a chip, a plurality of bonding wires, an encapsulant, and a plurality of solder balls. A plurality of ball pads are formed on the bottom surface of the substrate for solder ball placement. The near-substrate-scale die-attaching layer is formed on the top surface of the substrate covering most of the top surface above the ball pads without extending to the edges of the top surface. The active surface of the chip is attached to a first portion of the near-substrate-scale die-attaching layer and is electrically connected to the substrate by the bonding wires. The encapsulant is formed above the top surface of the substrate to cover a second portion of the near-substrate-scale die-attaching layer extending between the substrate and the encapsulant. Therefore, without adding extra components, the intense thermal stresses imposed on some specific solder balls at the corners of the bottom surface of the substrate or under the edges of the chip will be reduced. During on-board TCT, the solder balls will not easily be broken so that the reliability of IC package is enhanced. Moreover, the near-substrate-scale die-attaching layer is completely encapsulated by the encapsulant 250 to have a better resistance to moisture.

### FIELD OF THE INVENTION

The present invention relates to an IC package, and more particularly, to a Substrate-On-Chip, SOC, IC package with a near-substrate-scale die-attaching layer.

### BACKGROUND OF THE INVENTION

Substrate-On-Chip, SOC, packages are well-developed IC packages where substrates are attached to the active surfaces of the chips which are similar to the leads of the Lead-On-Chip packages attached to the active surfaces of the chips. Then, the chips and the substrates are electrically connected by bonding wires. Then, encapsulation and ball placement are followed. SOC packages are also called “Window BGA” or “Fine-pitch BGA”.

As shown in FIG. 1 and FIG. 3, a conventional IC package 100 primarily includes a substrate 110, a die-attaching layer 120, a chip 130, a plurality of bonding wires 140, an encapsulation 150 and a plurality of solder balls 160. The substrate 110 has a top surface 111, a bottom surface 112 and a plurality of ball pads 113 where the ball pads 113 are formed at the bottom surface 112. Normally the substrate 110 further has a slot 114 for passing through the bonding wires 140. As shown in FIG. 2, the die-attaching layer 120 formed on the top surface 111 of the substrate 110 has a size corresponding to the chip 130 for chip attaching. The active surface 131 of the chip 130 is attached to the substrate 110 by the die-attaching layer 120 where the dimension of the die-attaching layer 120 is slightly larger than the chip 130. As shown in FIG. 1 again, a plurality of bonding pads 132 of the chip 130 are electrically connected to the substrate 110 by a plurality of bonding wires 140 passing through the slot 114. The encapsulation 150 is formed over the top surface 111 and in the slot 114 of the substrate 110 to encapsulate the chip 130, the die-attaching layer 120, and the bonding wires 140. The solder balls 160 are placed on the ball pads 113. The IC package 100 is surface-mounted to an external printed circuit board, not shown in the figure, by the solder balls 160.

In order to test the reliability of IC packages, a board-level temperature cycle test, TCT, will be performed where the surface-mounted IC packages 100 will go through repeated cycles of high temperatures and low temperatures. Since the Coefficient of Thermal Expansion, CTE, of the IC package 100 is mismatched with the one of the external printed circuit board, therefore, thermal stresses will concentrate at some specific solder balls 160 causing cracks which leading to the resistance increase of signal transmission and, eventually, leading to electrical open, i.e., device failure. As shown in FIG. 2 and FIG. 3, normally, the solder balls 160 which are easily cracked under concentrated thermal stresses are located at the ball pads 113A, i.e., at the corners of the bottom surface 112 of the substrate 110 or under the edges of the chip 130. As shown in FIG. 2 again, some of the ball pads 113A located the bottom surface 112 of the substrate 110 are partially or completely outside the footprints of the die-attaching layer 120 on the top surface 111 of the substrate 110. Moreover, the corresponding top surface 111 of the substrate 110 above the ball pads 113A are directly encapsulated by the encapsulant 150.

### SUMMARY OF THE INVENTION

The main purpose of the present invention is to provide an IC package using a near-substrate-scale die-attaching layer having the covered area different from a conventional die-attaching layer so that the corresponding top surface of the substrate above the ball pads is covered by the near-substrate-scale die-attaching layer instead of an encapsulant so that, without extra components, the thermal stresses concentrated on some specific solder balls can be reduced. Therefore, during board-level TCT, solder balls will not easily be cracked.

The second purpose of the present invention is to provide an IC package having a near-substrate-scale die-attaching layer completely encapsulated to enhance moisture resistance besides thermal stress resistance.

According to the present invention, an IC package mainly comprises a substrate, a near-substrate-scale die-attaching layer, a chip, a plurality of bonding wires, an encapsulant and a plurality of solder balls. The substrate has a top surface and a bottom surface where a plurality of ball pads are formed on the bottom surface. The near-substrate-scale die-attaching layer covers most of the top surface of the substrate above the corresponding ball pads but not extending to the edges of the top surface. A chip is disposed on the top surface of the substrate where the chip has an active surface with a plurality of bonding pads thereon. The active surface or the back surface of the chip is attached to a first portion of the near-substrate-scale die-attaching layer as Window BGA, PBGA or FBGA. The bonding pads are electrically connected to the substrate by the bonding wires. The encapsulant is formed above the top surface of the substrate to encapsulate a second portion of the near-substrate-scale die-attaching layer and the bonding wires.

### DESCRIPTION OF THE DRAWINGS

FIG. 1 shows a cross-sectional view along the shorter sides of a conventional SOC package.

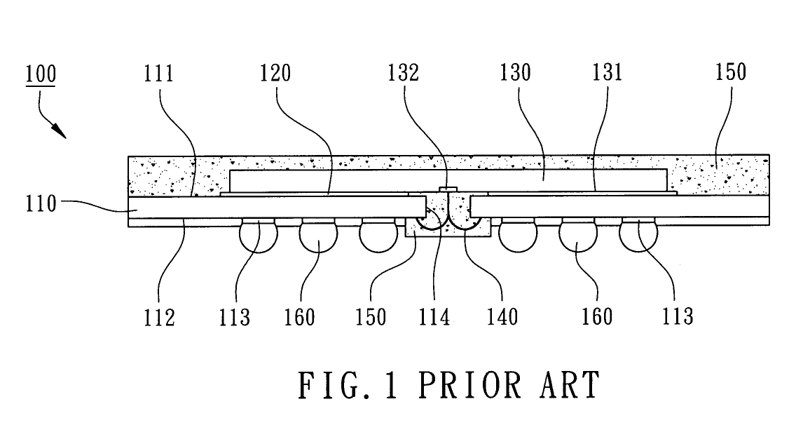

FIG. 2 shows a top view of a substrate and a chip-attaching layer of the conventional SOC package.

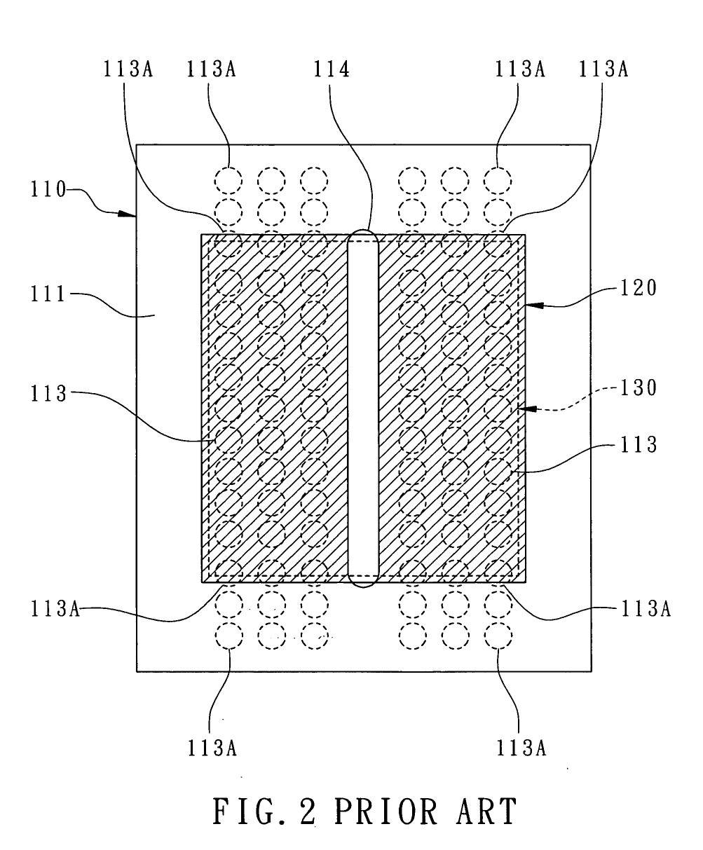

FIG. 3 shows a cross-sectional view along the longer sides of the conventional SOC package.

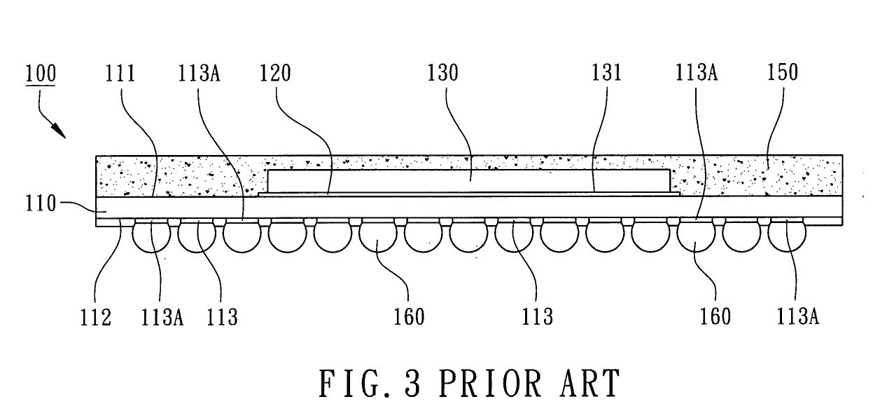

FIG. 4 shows a cross-sectional view along the shorter sides of an IC package using a near-substrate-scale die-attaching layer according to the embodiment of the present invention.

FIG. 5 shows a top view of a substrate and a chip-attaching layer of the IC package according to the embodiment of the present invention.

FIG. 6 shows a cross-sectional view along the longer sides of the IC package according to the embodiment of the present invention.

### DETAIL DESCRIPTION OF THE INVENTION

Please refer to the attached drawings, the present invention will be described by means of embodiment(s) below.

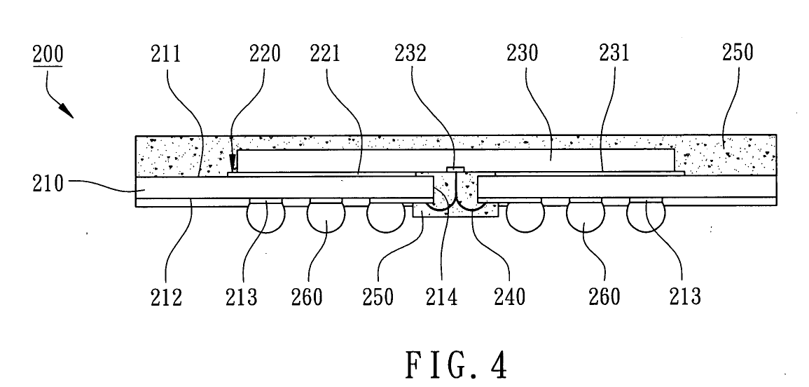

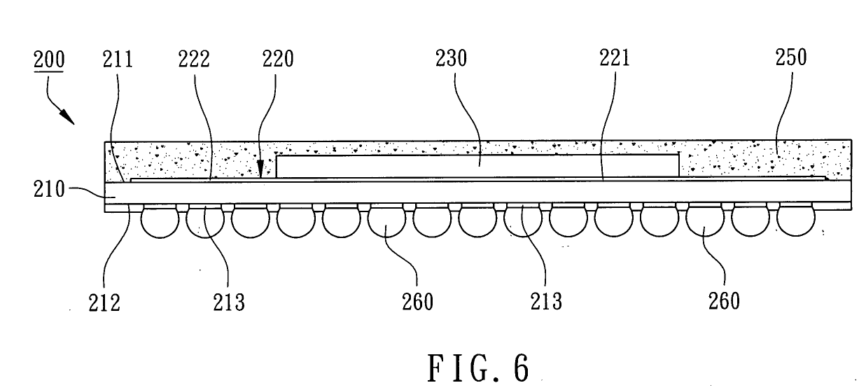

According to the first embodiment of the present invention, as shown in FIG. 4 and FIG. 6, the IC package 200 mainly includes a substrate 210, a near-substrate-scale die-attaching layer 220, a chip 230, a plurality of bonding wires 240, an encapsulant 250 and a plurality of solder balls 260. The substrate 210 has a top surface 211 and a bottom surface 212 where a plurality of ball pads 213 with the corresponding traces, not shown in the figure, are formed on the bottom surface 212. The substrate 210 can be a single-layer or multi-layer printed circuit board.

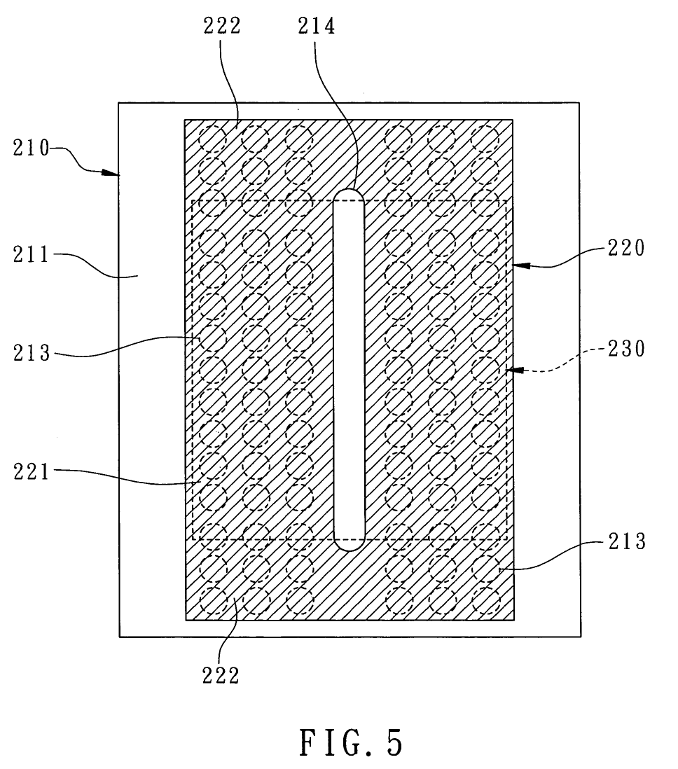

The top surface 211 of the substrate 210 is almost covered by the near-substrate-scale die-attaching layer 220, the shadow area as shown in FIG. 5. The near-substrate-scale die-attaching layer 220 primarily has a first portion 221 and at least a second portion 222 where the first portion 221 is used to attach the chip 230 and the second portion 222 is used to reduce the direct contact area of the encapsulant 250 on the top surface 211 of the substrate 210 as shown in FIG. 6. Moreover, the covered area of the near-substrate-scale die-attaching layer 220 is approximately the same as the top surface 211 of the substrate 210. Normally, the near-substrate-scale die-attaching layer 220 will cover more than 70% of the top surface 211 of the substrate 210. In the present embodiment, the near-substrate-scale die-attaching layer 220 is rectangular which will cover the corresponding top surface 211 of the substrate 210 above all of the ball pads 213 without extending to the edges of the top surface 211.

The chip 230 is disposed on the top surface 211 of the substrate 210 where the chip 230 has an active surface 231. A plurality of bonding pads 232 are formed on the active surface 231 of the chip 230. The active surface 231 or the back surface of the chip 230 is attached to the first portion 221 of the near-substrate-scale die-attaching layer 220. In the present embodiment, the covered area of the near-substrate-scale die-attaching layer 220 is almost equal to the one of the top surface 211 of the substrate 210.

As shown in FIG. 4 and FIG. 5, the bonding pads 232 are electrically connected to the substrate 210 by the bonding wires 240. The substrate 210 has a slot 214 for passing through the bonding wires 240 from the bonding pads 232 to the substrate 210 where the slot 214 penetrates the top surface 211 and the bottom surface 212 of the substrate 210. As shown in FIG. 5 again, the length of the slot 214 can be longer than the one of the corresponding chip 230. In a different embodiment, the slot 214 is long enough to cut through the whole substrate 210 so that the substrate 210 is assembled by two pieces or multiple pieces.

As shown in FIG. 4 and FIG. 6, the encapsulant 250 is formed above the top surface 211 of the substrate 210 to cover the second portion 222 of the near-substrate-scale die-attaching layer 220 to completely encapsulate the near-substrate-scale die-attaching layer 220 and the bonding wires 240, i.e., the edges of the near-substrate-scale die-attaching layer 220 are all encapsulated by the encapsulant 250 so that the near-substrate-scale die-attaching layer 220 will not be exposed to enhance the moisture resistance of the IC package 200. Furthermore, the encapsulant 250 completely encapsulates the chip 230. In the present embodiment, the Young's modulus of the near-substrate-scale die-attaching layer 220 is smaller than the one of the encapsulant 250. Normally, the Young's modului of the encapsulant 250 ranges from 20 GPa to 30 GPa at 25° C. where the ones of the near-substrate-scale die-attaching layer 220 is smaller than 1 GPa, especially ranging from 0.005 GPa to 1 GPa at 25° C. to provide a buffer to absorb and transfer the thermal stresses. Accordingly, the second portion 222 is a stress-buffering layer extending between the substrate 210 and the encapsulant 250. The encapsulant 250 will not firmly catch the substrate 210.

As shown in FIG. 5 again, in the present embodiment, the top surface 211 of the substrate 210 can be rectangular and the second portion 222 of the near-substrate-scale die-attaching layer 220 is close to the shorter sides of the top surface 211 of the substrate 210 comparing to the first portion 221.

The solder balls 260 are disposed on the ball pads 213 so that the IC package 200 can electrically connect to an external printed circuit board by the solder balls 260. In the present embodiment, the ball pads 213 can be signal pads which are electrically connected to the chip 230.

Therefore, as shown in FIG. 6, the IC package 200 mentioned above, all the solder balls 260 are electrically connected to the corresponding ball pads 213. Most of the top surface 211 of the substrate 210 above the corresponding ball pads 213 disposed on the bottom surface 212 of the substrate 210 is covered by the near-substrate-scale die-attaching layer 220 and will not directly contact with the encapsulant 250. As shown in FIG. 5, since most of the top surface 211 of the substrate 210 above the ball pads 213 is covered by the near-substrate-scale die-attaching layer 220, therefore, the edges of the chip 230 will not impose extra stresses on the adjacent ball pads 213 under the chip 230. Without adding extra components, the intense thermal stresses imposed on some specific solder balls 260 at the corners of the bottom surface 212 of the substrate 210 or under the edges of the chip 230 will be reduced. During on-board TCT, the solder balls 260 will not easily be broken so that the reliability of IC package 200 is enhanced. Moreover, the near-substrate-scale die-attaching layer 220 including the second portion 222 is completely encapsulate by the encapsulant 250 to have a better resistance to moisture.

The above description of embodiments of this invention is intended to be illustrative and not limiting. Other embodiments of this invention will be obvious to those skilled in the art in view of the above disclosure.

What is claimed is:

1. An IC package comprising:
a substrate having a top surface, a bottom surface and a plurality of ball pads disposed on the bottom surface;
a near-substrate-scale die-attaching layer formed on the top surface of the substrate but not extending to the edges of the top surface;
a chip disposed on the top surface of the substrate and having an active surface with a plurality of bonding pads formed thereon, wherein the near-substrate-scale die-attaching layer have a first portion and a second portion, when the chip is attached to the first portion, the second portion is exposed from the chip in a manner that the near-substrate-scale die-attaching layer covers the corresponding top surface above all of the ball pads;
a plurality of bonding wires electrically connecting the bonding pads to the substrate;
an encapsulant formed above the top surface of the substrate to cover the second portion of the near-substrate-scale die-attaching layer to completely encapsulate the near-substrate-scale die-attaching layer and the bonding wires; and
a plurality of solder balls disposed on the ball pads.

2. The IC package of claim 1, wherein the near-substrate-scale die-attaching layer has a covered area on the top surface close to the area of the top surface of the substrate.

3. The IC package of claim 2, wherein the covered area is more than 70% of the area of the top surface of the substrate.

4. The IC package of claim 1, wherein the near-substrate-scale die-attaching layer is rectangular.

5. The IC package of claim 1, wherein the active surface of the chip is attached to the first portion of the near-substrate-scale die-attaching layer.

6. The IC package of claim 5, wherein the substrate has a slot for passing through the bonding wires to the bonding pads.

7. The IC package of claim 1, wherein the Young's modulus of the near-substrate-scale die-attaching layer is smaller than the one of the encapsulant.

8. The IC package of claim 1, wherein the substrate is a single-layer or multi-layer printed circuit board.

9. The IC package of claim 1, wherein the encapsulant completely encapsulates the chip.

10. The IC package of claim 1, wherein the ball pads are signal pads electrically connected to the chip.

11. The IC package of claim 1, wherein the top surface of the substrate is rectangular and the second portion of the near-substrate-scale die-attaching layer is closer to the shorter edges of the top surface than the first portion of the near-substrate-scale die-attaching layer.

12. The IC package of claim 1, wherein all of the ball pads on the bottom surface of the substrate are disposed under the footprint of the near-substrate-scale die-attaching layer.
